(19) United States
(12) Patent Application Publication
(10) Pub. No.: US 2018/0150248 A1
(43) Pub. Date: May 31, 2018

(54) MEMORY DEVICE, SEMICONDUCTOR SYSTEM INCLUDING THE SAME, AND METHOD FOR DRIVING THE SEMICONDUCTOR SYSTEM

(71) Applicant: SK hynix Inc., Gyeonggi-do (KR)

(72) Inventors: Jung-Hyun KWON, Seoul (KR); Sang-Gu JO, Gyeonggi-do (KR); Sung-Eun LEE, Gyeonggi-do (KR)

(21) Appl. No.: 15/679,585

(22) Filed: Aug. 17, 2017

(30) Foreign Application Priority Data
Nov. 30, 2016 (KR) 10-2016-0161501

(51) Int. Cl. G06F 3/06; G11C 7/10; G11C 11/56; G11C 11/4093

(52) U.S. Cl. CPC G06F 3/0619; G06F 3/0659; G11C 7/1066; G11C 11/56; G11C 11/4093; G11C 7/1006

(57) ABSTRACT

A semiconductor device includes at least one normal block suitable for storing normal data; at least one sample block suitable for storing sample data; a phenomenon analysis block suitable for generating at least one phenomenon analysis signal based on the sample data; and a control block suitable for controlling a level of reference data required when the normal data are read based on the at least one phenomenon analysis signal.

### CROSS-REFERENCE TO RELATED APPLICATIONS

The present application claims priority under 35 U.S.C 119(a) to Korean Patent Application No. 10-2016-0161501, filed on Nov. 30, 2016, which is herein incorporated by reference in its entirety.

### BACKGROUND

### 1. Field

Various embodiments of the present invention relate generally to a semiconductor design technology and, more particularly, to a semiconductor device, a semiconductor system including the semiconductor device, and a method for driving the semiconductor system.

### 2. Description of the Related Art

As electronic devices become smaller with low power consumption, higher performance, and multi-functionality, semiconductor memory devices capable of storing information in these electronic devices for example, computers, portable communication devices, or the like, are increasingly in demand. Such semiconductor memory devices may use a resistance variable element that switches between different resistance states according to a voltage or current applied to such an element. Semiconductor memory devices include, for example, resistive random access memory (RRAM) devices, phase change random access memory (PRAM) devices, ferroelectric random access memory (FRAM) devices, magneto-resistive random access memory (MRAM) devices, E-fuses, or the like.

### SUMMARY

Exemplary embodiments of the present invention are directed to a semiconductor device capable of easily analyzing and avoiding a drift phenomenon or a retention phenomenon occurring in a storage region or block, a semiconductor system including the semiconductor device, and a method for driving the semiconductor system.

In accordance with an embodiment of the present invention, a semiconductor device may include: at least one normal block suitable for storing normal data; at least one sample block suitable for storing sample data; a phenomenon analysis block suitable for generating at least one phenomenon analysis signal based on the sample data; and a control block suitable for controlling a level of reference data required when the normal data are read based on the at least one phenomenon analysis signal.

The sample data may have equal proportions of two or more data values that the normal data have.

The control block may include: a reference data generation unit suitable for generating a plurality of data, each having different levels; a reference data selection unit suitable for selecting one of the plurality of data as the reference data based on a selection control signal; and a selection control unit suitable for generating the selection control signal based on the at least one phenomenon analysis signal.

The phenomenon analysis block may include: a comparison data storage unit suitable for storing comparison data having the same data pattern as a predetermined data pattern of the sample data which have equal proportion of two or more data values that the normal data have; a data comparison unit suitable for comparing the comparison data with the sample data; and a rate calculation unit suitable for generating the at least one phenomenon analysis signal, wherein the at least one phenomenon analysis signal includes first and second phenomenon analysis signals corresponding to rates of the data values based on a comparison result of the data comparison unit.

The semiconductor device may further include: a read circuit block suitable for reading at least one of the normal data or reading the sample data based on the reference data.

The sample block may include a start-gap block.

The sample block may be disposed adjacent to the normal block or in the normal block.

In accordance with an embodiment of the present invention, a semiconductor system may include: a semiconductor device suitable for storing normal data and sample data, wherein the sample data represent characteristics of the normal data; and a control device suitable for analyzing phenomena occurring in the normal data based on the sample data, wherein the phenomena include a drift phenomenon and a retention phenomenon.

The sample data nay have equal proportions of two or more data values that the normal data have.

The semiconductor device may control a level of a reference data required when at least one of the normal data is read based on at least one phenomenon analysis signal, which correspond to a result of analyzing the phenomena, generated from the control device.

The semiconductor device may include: at least one normal block suitable for storing the normal data; at least one sample block suitable for storing the sample data; and a control block suitable for controlling the level of the reference data based on the at least one phenomenon analysis signal.

The control block may include: a reference data generation unit suitable for generating a plurality of data, each having different levels; a reference data selection unit suitable for selecting one of the plurality of data as the reference data based on a selection control signal; and a selection control unit suitable for generating the selection control signal based on he at least one phenomenon analysis signal.

The semiconductor device may further include: a read circuit block suitable for reading at least one of the normal data or reading the sample data based on the reference data.

The sample block may include a start-gap block.

The sample block may be disposed adjacent to the normal block or in the normal block.

The control device may control a recovery operation or a scrubbing operation of the semiconductor device based on the result of analyzing the phenomena.

The control device may include: a phenomenon analysis block suitable for generating first and second phenomenon analysis signals corresponding to the phenomena based on the sample data; a recovery control block suitable for controlling the recovery operation based on the first phenomenon analysis signal; and a scrubbing control block suitable for controlling the scrubbing operation based on the second phenomenon analysis signal.

The phenomenon analysis block may include; a comparison data storage unit suitable for storing comparison data having the same data pattern as a predetermined data pattern of the sample data which have an equal proportion of two or more data values that the normal data have; a data comparison unit suitable for comparing the comparison data with the sample data; and a rate calculation unit suitable for generating the first and second phenomenon analysis signals corresponding to rates of the data values based on a comparison result of the data comparison unit.

The control device may write the normal data in the semiconductor device through a wear leveling operation.

In accordance with an embodiment of the present invention, a method for driving a semiconductor system may include: analyzing whether a drift phenomenon occurs or a retention phenomenon occurs in at least one normal data based on sample data; controlling a reference data based on a result of the analysis; and reading the at least one normal data based on the reference data.

The analyzing may include analyzing whether the drift phenomenon occurs or the retention phenomenon occurs in the at least one normal data based on rates of data values of the sample data.

The controlling of the reference data may include: when the drift phenomenon occurs as the result of the analysis increasing a voltage level of the reference data; and when the retention phenomenon occurs as the result of the analysis, decreasing the voltage level of the reference data.

The method may further include: when the drift phenomenon occurs as the result of the analysis, performing a recovery operation on a normal data block where the normal data are stored; and when the retention phenomenon occurs as the result of the analysis, performing a scrubbing operation on the normal data block.

The analyzing of the phenomena and the controlling of the reference data are carried out for each normal read operation, for each predetermined period or in consideration of an elapsed time after the normal data are written.

### BRIEF DESCRIPTION OF THE DRAWINGS

FIG. 1 is a block diagram illustrating a semiconductor system in accordance with an embodiment of the present invention.

FIG. 2 is a block diagram illustrating a semiconductor device shown in FIG. 1.

FIG. 3 is a block diagram illustrating a control block shown in FIG. 2.

FIG. 4 is a block diagram illustrating a control device shown in FIG. 1.

FIG. 5 is a block diagram illustrating a phenomenon analysis block shown in FIG. 4.

FIG. 6 is a flow chart illustrating an operation of the semiconductor system shown in FIG. 1.

FIG. 7 is a flow chart illustrating an operation of the semiconductor system shown in FIG. 1.

### DETAILED DESCRIPTION

Various embodiments of the present invention will be described below in more detail with reference to the accompanying drawings. These embodiments are provided so that this disclosure is thorough and complete. All “embodiments” referred to in this disclosure refer to embodiments of the inventive concept disclosed herein. The embodiments presented are merely examples and are not intended to limit the scope of the invention.

Moreover, it is noted that the terminology used herein is for the purpose of describing the embodiments only and is not intended to be limiting of the invention. As used herein, singular forms are intended to include the plural forms as well, unless the context clearly indicates otherwise. It will be further understood that the terms “comprises,” “comprising,” “includes” and/or “including” when used in this specification, indicate the presence of stated features, but do not preclude the presence or addition of one or more other non-stated features. As used herein, the term “and/or” indicates any and all combinations of one or more of the associated listed items. It is also noted that in this specification, “connected/coupled” refers to one component not only directly coupling another component but also indirectly coupling another component through an intermediate component.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments.

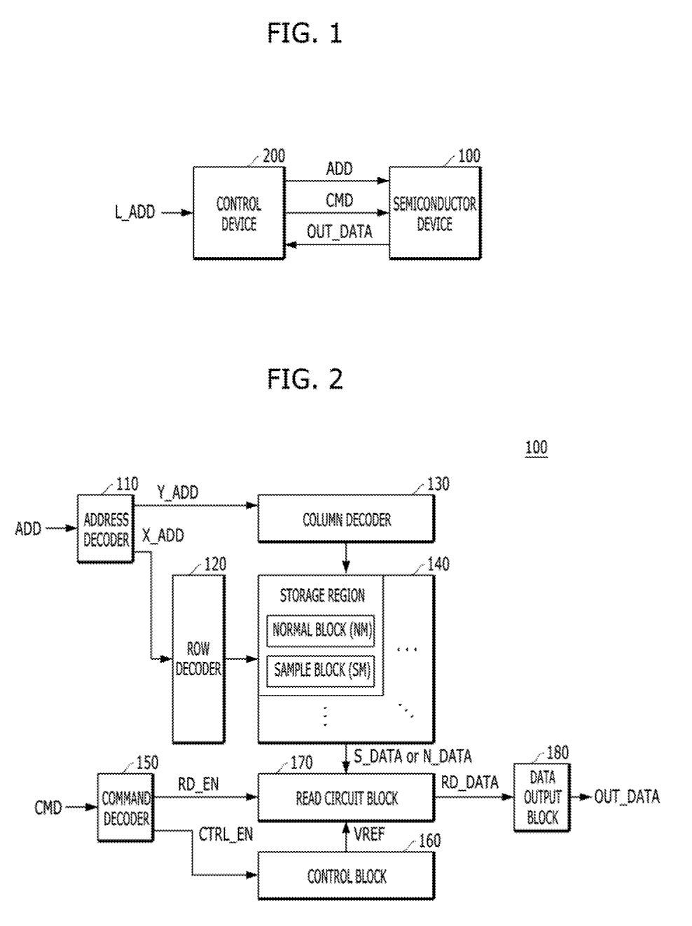

FIG. 1 is a block diagram illustrating a semiconductor system in accordance with an embodiment of the present invention.

Referring to FIG. 1, the semiconductor system may include a semiconductor device 100, and a control device 200.

The semiconductor device 100 may store normal data N_DATA and sample data S_DATA. The semiconductor device 100 may supply the normal data N_DATA or sample data S_DATA as output data OUT_DATA to the control device 200 based on an address signal ADD and a command signal CMD that are generated from the control device 200.

The normal data N_DATA may correspond to write data (not illustrated) supplied from the control device 200. Each of the normal data N_DATA may have one of two or more data values. For example, the normal data N_DATA may have a data value “1” corresponding to a logic high level or a data value “0” corresponding to a logic low level. The normal data N_DATA may have data values that unintentionally change due to a drift phenomenon or a retention phenomenon. The drift phenomenon and the retention phenomenon will be described below.

The sample data S_DATA may represent characteristics of the normal data N_DATA. For example, the sample data S_DATA may have data values that unintentionally change due to the drift phenomenon or the retention phenomenon, similar to the normal data N_DATA. The sample data S_DATA may have equal proportions of two or more data values that the normal data N_DATA have. For example, the sample data S_DATA may have the same number of the data value “1” as the number of the data value “0”. The sample data S_DATA may be written with a predetermined data pattern. For example, the sample data S_DATA may be written with a repetitive pattern of the data value “1” and the data value “0”, namely, a data pattern of “1010 . . . ”.

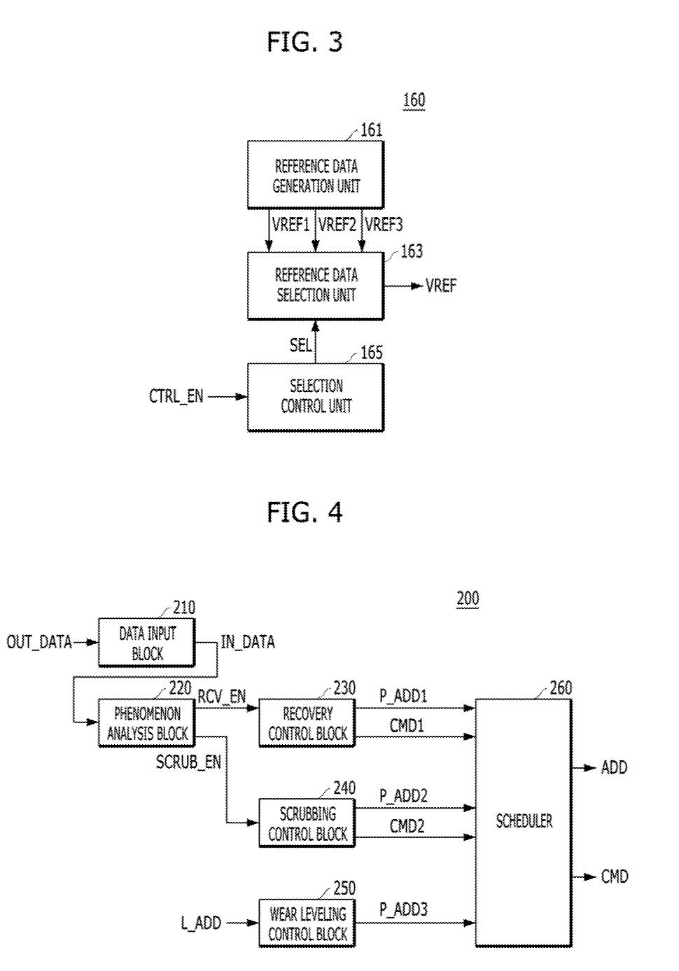

The semiconductor device 100 may generate a reference data VREF required when reading the normal data N_DATA and adjust a level of the reference data VREF, based on the command signal CMD, as will be described below in detail with reference to FIGS. 2 and 3.

The semiconductor device 100 may perform a recovery operation or a scrubbing operation based on the address signal ADD and the command signal CMD. The recovery operation may include a series of processes of returning to a valid data value by applying a recovery pulse to a storage cell whose data value changes due to the drift phenomenon. The scrubbing operation may include a series of processes of reading data from a storage cell whose data value changes due to the retention phenomenon, correcting the read data through an error correction code (ECC) operation and rewriting the corrected data in the storage cell. Since the recovery operation and the scrubbing operation are widely known to those skilled in the art, detailed descriptions thereof will be omitted.

The control device 200 may analyze the phenomena occurring in the normal data N_DATA based on the output data OUT_DATA corresponding to the sample data S_DATA. For example, the control device 200 may determine that the drift phenomenon occurs in the normal data N_DATA when the number of the data value “0” is greater than the number of the data value “1” among the sample data S_DATA and that the retention phenomenon occurs in the normal data N_DATA when the number of the data value “1” is greater than the number of data value “0” among the sample data S_DATA.

The control device 200 may control the semiconductor device 100 to perform either of the recovery operation and the scrubbing operation, and to adjust the level of the reference data VREF, by supplying the address signal ADD and the command signal CMD which correspond to the analysis result of the semiconductor device 100. The control device 200 may control the semiconductor device 100 to perform either of the recovery operation and the scrubbing operation or to adjust the level of the reference data VREF according to the analysis result.

The control device 200 may perform a wear leveling operation when supplying the write data to the semiconductor device 100. For example, the control device 200 may perform a start-gap wear leveling operation. Since the start-gap wear leveling operation is widely known to those skilled in the art, detailed descriptions thereof will be omitted.

FIG. 2 is a block diagram illustrating the semiconductor device 100 shown in FIG. 1.

It should be understood that structures related to the recovery operation, structures related to the retention operation and structures related to the wear leveling operation are omitted in FIG. 2. Since the recovery operation, the retention operation and the wear leveling operation are widely known to those skilled in the art, descriptions of their structures are omitted.

Referring to FIG. 2, the semiconductor device 100 may include an address decoder 110, a row decoder 120, a column decoder 130, a storage cell array 140, a command decoder 150, a control block 160, a read circuit block 170, and a data output block 180.

The address decoder 110 may generate a row address signal X_ADD and a column address signal Y_ADD based on the address signal ADD.

The row decoder 120 may select at least one of a plurality of row lines (not illustrated) included in the storage cell array 140 based on the row address signal X_ADD.

The column decoder 130 may select at least one of a plurality of column lines (not illustrated) included in the storage cell array 140 based on the column address signal Y_ADD.

The storage cell array 140 may include a plurality of storage regions coupled to the row fines and the column lines. Each of the storage regions may include a normal block NM and a sample block SM.

The normal block NM may include a plurality of normal storage cells (not illustrated) coupled to cross points between two or more row lines and two or more column lines. The normal storage cells may store the normal data N_DATA. For example, each of the normal storage cells may include a phase change storage cell. The phase change storage cell may store data based on a resistance state/degree of a phase change material. The phase change storage cell may have characteristics in which the resistance state changes after the data are written. For example, a phenomenon in which the storage cell changes from a low resistance state to a high resistance state may be referred to as the drift phenomenon, and a phenomenon in which the storage cell changes from a high resistance state to a low resistance state may be referred to as the retention phenomenon.

The sample block SM may be disposed on one side of the normal block NM or in the normal block NM. The sample block SM may include a plurality of sample storage cells (not illustrated) coupled to cross points between one or more row lines and two or more column lines. For example, each of the sample storage cells may include the phase change storage cell. The sample storage cells may represent characteristics of the normal storage cells. That is, the drift phenomenon or the retention phenomenon may occur in each of the sample storage cells.

The sample block SM may include a gap block required for the start-gap wear leveling operation. For example, the gap block may be included in the normal block as an extra line block. The gap block may be used as the sample block SM.

The command decoder 150 may generate a control signal CTRL_EN corresponding to a first phenomenon analysis signal RCV_EN or a second phenomenon analysis signal SCRUB_EN, which is to be described below, and a read control signal RD_EN activated during a read operation, based on the command signal CMD.

The control block 160 may generate the reference data VREF and control the level of the reference data VREF based on the control signal CTRL_EN. For example, the control block 160 may generate the reference data VREF having a first level, which is previously set, based on the control signal CTRL_EN having a default value. The control block 160 may generate the reference data VREF having a second level that is higher than the first level based on the control signal CTRL_EN corresponding to the first phenomenon analysis signal RCV_EN. The control block 160 may generate the reference data VREF having a third level that is lower than the first level based on the control signal CTRL_EN corresponding to the second phenomenon analysis signal SCRUB_EN. The control signal CTRL_EN may be a multi-bit signal.

The read circuit block 170 may be enabled based on the read control signal RD_EN and read the normal data N_DATA or the sample data S_DATA based on the reference data VREF. For example, the read circuit block 170 may compare the normal data N_DATA with the reference data VREF and generate read data RD_DATA corresponding to the comparison result. Also, the read circuit block 170 may compare the sample data S_DATA with the reference data VREF and generate the read data RD_DATA corresponding to the comparison result.

The data output block 180 may output the read data RD_DATA as the output data OUT_DATA to the control device 200.

FIG. 3 is a block diagram illustrating the control block 160 shown in FIG. 2.

Referring to FIG. 3, the control block 160 may include a reference data generation unit 161, a reference data selection unit 163, and a selection control unit 165.

The reference data generation unit 161 may generate first to third data VREF1, VREF2 and VREF3. The first to third data VREF1, VREF2 and VREF3 may have different levels. For example, the first data VREF1 may have a first voltage level corresponding to the first level as a first reference voltage, and the second data VREF2 may have a second voltage level corresponding to the second level as a second reference voltage, and the third data VREF3 may have a third voltage level corresponding to the third level as a third reference voltage.

The reference data selection unit 163 may select one of the first to third data VREF1, VREF2 and VREF3 as the reference data VREF based on a selection control signal SEL.

The selection control unit 165 may generate the selection control signal SEL based on the control signal CTRL_EN. For example, the selection control unit 165 may include a mode register.

FIG. 4 is a block diagram illustrating the control device 200 shown in FIG. 1.

Referring to FIG. 4, the control device 200 may include a data input block 210, a phenomenon analysis block 220, a recovery control block 230, a scrubbing control block 240 a wear leveling control block 250, and a scheduler 260.

The data input block 210 may generate input data IN_DATA based on the output data OUT_DATA supplied from the semiconductor device 100.

The phenomenon analysis block 220 may generate, the first phenomenon analysis signal RCV_EN corresponding to the drift phenomenon and the second phenomenon analysis signal SCRUB_EN corresponding to the retention phenomenon, based on the input data IN_DATA corresponding to the sample data S_DATA.

The recovery control block 230 may generate a first address signal P_ADD1 and a first command signal CMD1 which correspond to the recovery operation, based on the first phenomenon analysis signal RCV_EN.

The scrubbing control block 240 may generate a second address signal P_ADD2 and a second command signal CMD2 which correspond to the scrubbing operation, based on the second phenomenon analysis signal SCRUB_EN.

The wear leveling control block 250 may generate a third address signal P_ADD3 based on an external address signal L_ADD. The external address signal L_ADD may include a logical address signal, and the third address signal P_ADD3 may include a physical address signal. For example, the wear leveling control block 250 may perform the start-gap wear leveling operation. Since the number of times that storage cells included in each storage region are written is equally controllable when a wear leveling operation including the start-gap wear leveling operation is performed, environments that can have the same characteristics may be created in the storage cells.

The scheduler 260 may output one of the first to third address signals P_ADD1, P_ADD2 and P_ADD3 as the address signal ADD and output one of the first and second command signals CMD1 and CMD2 as the command signal CMD.

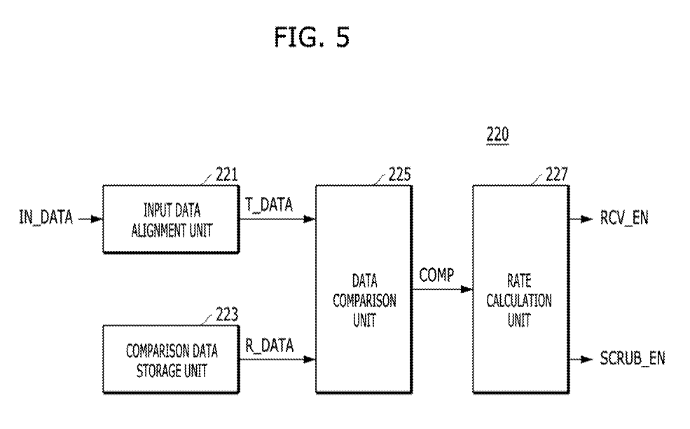

FIG. 5 is a block diagram illustrating the phenomenon analysis block 220 shown in FIG. 4.

Referring to FIG. 5, the phenomenon analysis block 220 may include an input data alignment unit 221, a comparison data storage unit 223, a data comparison unit 225, and a rate calculation unit 227.

The input data alignment unit 221 may align the input data IN_DATA corresponding to the sample data S_DATA.

The comparison data storage unit 223 may store comparison data R_DATA having the predetermined data pattern. For example, the comparison data R_DATA may have the data pattern of “1010 . . . ” and correspond to the sample data S_DATA in a one-to-one manner.

The data comparison unit 225 may compare target data T_DATA outputted from the input data alignment unit 221 with the comparison data R_DATA, respectively, and generate a comparison signal COMP corresponding to the comparison result. For example, the data comparison unit 225 may compare respective data values of the target data T_DATA with respective data values of the comparison data R_DATA whether those are the same or different.

The rate calculation unit 227 may calculate rates of the data values of the sample data S_DATA based on the comparison signal COMP and generate the first and second phenomenon analysis signals RCV_EN and SCRUB_EN corresponding to the calculation result. For example, the rate calculation unit 227 may count the number of the same data values from the odd-numbered target data among the target data T_DATA and the odd-numbered comparison data among the comparison data R_DATA and count the number of the same data values from the even-numbered target data among the target data T_DATA and the even-numbered comparison data among the comparison data R_DATA, thereby calculating the rates of the data values of the sample data S_DATA. When a rate of the data value “0” among the data values of the sample data S_DATA is high, the rate calculation unit 227 may activate the first phenomenon analysis signal RCV_EN. When a rate of the data value “1” among the data values of the sample data S_DATA is high, the rate calculation unit 227 may activate the second phenomenon analysis signal SCRUB_EN. When the rate of the data value “0” among the data values of the sample data S_DATA is the same as the rate of the data value “1” among the data values of the sample data S_DATA, the rate calculation unit 227 may activate both of the first and second phenomenon analysis signals RCV_EN and SCRUB_EN.

Hereinafter an operation of the semiconductor system having the aforementioned structures in accordance with an embodiment of the present invention will be described.

An embodiment of the present invention may be directed to an operating method for the semiconductor system capable of restraining or ignoring characteristics in which the data values of the normal data N_DATA change due to the drift phenomenon or the retention phenomenon.

The operating method of the semiconductor system may be carried out according to various set conditions. For example, the operating method may be carried out for each predetermined period, during a normal read mode, during a predetermined mode such as a standby mode or in consideration of an elapsed time after the normal data N_DATA are written. Hereinafter, two examples of the operating method will be representatively described. As an example, the sample data S_DATA having two or more data values at the same rate are already written in each sample block SM included in the semiconductor device 100.

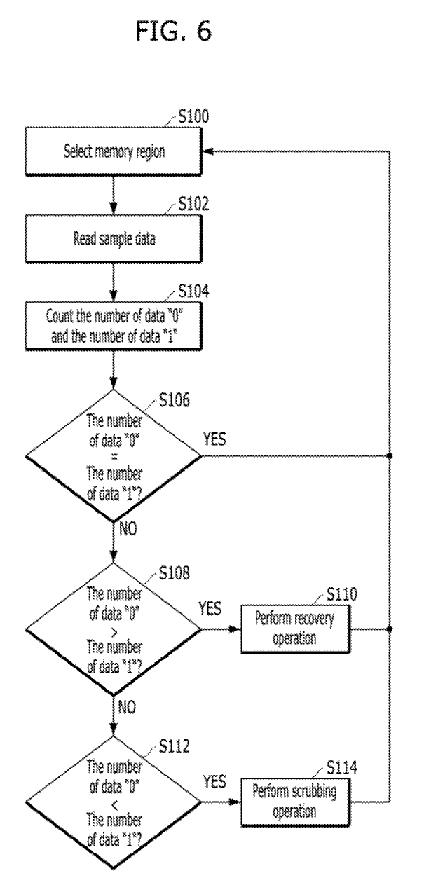

With reference to FIG. 6, the following descriptions will be made by exemplifying a case in which the operating method for the semiconductor system is carried out for each predetermined period.

FIG. 6 is a flowchart illustrating the operating method for the semiconductor system.

Referring to FIG. 6, the semiconductor device 100 may sequentially select a plurality of storage regions included in the storage cell array 140 based on a control of the control device 200.

When a storage region is selected from the storage regions in step S100, the semiconductor device 100 may supply the output data OUT_DATA corresponding to the sample data S_DATA to the control device 200 from the sample block SM included in the selected storage region in step S102. For example, the read circuit block 170 may generate the read data RD_DATA corresponding to the sample data S_DATA based on the reference data VREF. The sample data S_DATA may be read in the same order as when being written, and the reference data VREF may have the first level which is set as a default value. The data output block 180 may supply the read data RD_DATA as the output data OUT_DATA to the control device 200.

The control device 200 may indirectly analyze characteristics of the normal block NM inducted in the selected storage region of the storage cell array 140 based on the output data OUT_DATA. For example, the control device 200 may analyze whether the normal block NM has characteristics related to the drift phenomenon or characteristics related to the retention phenomenon based on rates of data values of the output data OUT_DATA. When the data input block 210 generates the input data IN_DATA corresponding to the output data OUT_DATA, the phenomenon analysis block 220 may analyze which phenomenon occurs between the drift phenomenon and the retention phenomenon in the normal block NM based on the input data IN_OUT. For example, the phenomenon analysis block 220 may analyze the phenomenon by counting the number of the data value “0” and the number of the data value “1”, which the input data IN_OUT have, in step S104.

When it is determined that the number of the data value “0” is the same as the number of the data value “1” in step S106, the control device 200 may select a next storage region by proceeding to the step S100.

Unlike this, when it is determined that the number of the data value “0” is greater than the number of the data value “1” in step S108, the control device 200 may determine that the drift phenomenon occurs in the normal block NM. The semiconductor device 100 may perform the recovery operation on the normal block NM under the control of the control device 200 in step S110. As the semiconductor device 100 performs the recovery operation, characteristics in which the data values of the normal data N_DATA change due to the drift phenomenon may be retrained.

When it is determined that the number of the data value “1” is greater than the number of the data value “0” in step S112, the control device 200 may determine that the retention phenomenon occurs in the normal block NM. The semiconductor device 100 may perform the scrubbing operation on the normal block NM under the control of the control device 200 in step S114. As the semiconductor device 100 performs the scrubbing operation, characteristics in which the data values of the normal data N_DATA change due to the retention phenomenon may be retrained.

The aforementioned processes S100 to S114 may be sequentially carried out for the other storage regions among the storage regions of the storage cell array 140.

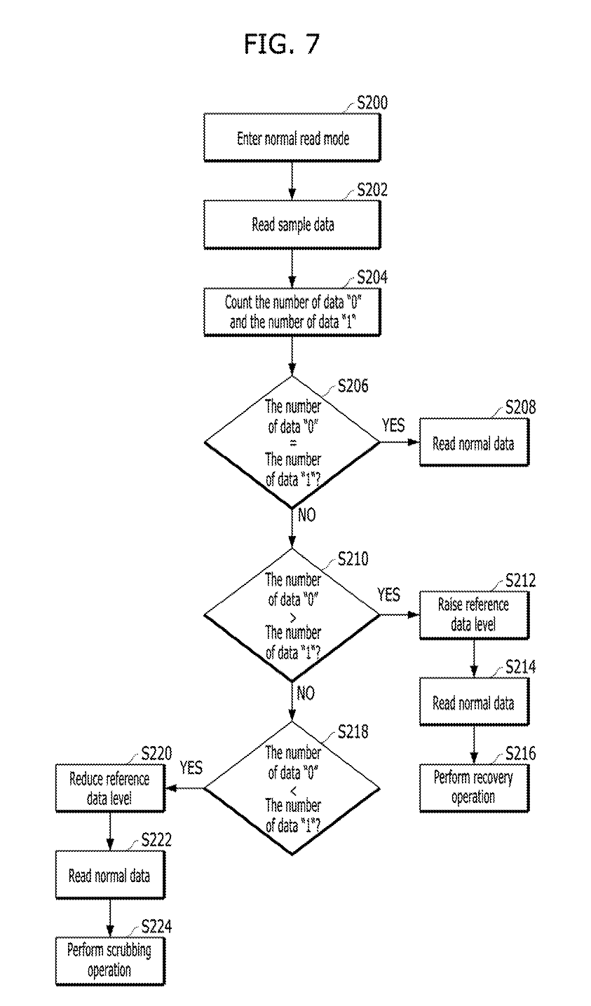

With reference to FIG. 7, the following descriptions will be made by exemplifying a case in which the operating method for the semiconductor system is carried out for each normal read mode.

FIG. 7 is a flowchart illustrating the operating method for the semiconductor system.

Referring to FIG. 7, when the semiconductor system enters the normal read mode in step S200, the semiconductor device 100 may select a read target storage region among a plurality of storage regions included in the storage cell array 140 based on a control of the control device 200.

The semiconductor device 100 may supply the output data OUT_DATA corresponding to the sample data S_DATA to the control device 200 from the sample block SM included in the read target storage region of the storage cell array 140 in step S202. For example, the read circuit block 170 may generate the read data RD_DATA corresponding to the sample data S_DATA based on the reference data VREF. The sample data S_DATA may be read in the same order as when being written, and the reference data VREF may have the first level which is set as a default value. The data output block 180 may supply the read data RD_DATA as the output data OUT_DATA to the control device 200.

The control device 200 may analyze characteristics of the normal block NM included in the read target storage region of the storage cell array 140 based on the output data OUT_DATA. For example, the control device 200 may analyze whether the normal block NM has characteristics related to the drift phenomenon or characteristics related to the retention phenomenon based on rates of data values of the output data OUT_DATA. When the data input block 210 generates the input data IN_DATA corresponding to the output data OUT_DATA, the phenomenon analysis block 220 may analyze which phenomenon occurs between the drift phenomenon and the retention phenomenon in the normal block NM based on the input data IN_OUT. For example, the phenomenon analysis block 220 may analyze the phenomenon by counting the number of the data value “0” and the number of the data value “1”, which the input data IN_OUT have, in step S204.

When it is determined that the number of the data value “0” is the same as the number of the data value “1” in step S206, the semiconductor device 100 may read at least one of the normal data N_DATA from the normal block NM based on the reference data VREF having the first level and output the output data OUT_DATA corresponding to the read normal data to the control device 200 in step S208.

When it is determined that the number of the data value “0” is greater than the number of the data value “1” in step S210, the control device 200 may determine that the drift phenomenon occurs in the normal block NM. The semiconductor device 100 may generate the reference data VREF having the second level that is higher than the first level under the control of the control device 200 in step S212. That is, the semiconductor device 100 may increase the level of the reference data VREF in step S212. Subsequently, the semiconductor device 100 may read at least one of the normal data N_DATA from the normal block NM based on the reference data VREF having the second level and output the output data OUT_DATA corresponding to the read normal data to the control device 200 in step S214. The semiconductor device 100 may read the normal data by raising or increasing a level of the reference data VREF, thereby ignoring characteristics n which the data values of the normal data N_DATA change due to the drift phenomenon. Subsequently, the semiconductor device 100 may perform the recovery operation on the normal block NM under the control of the control device 200 in step S216. However, if it is possible to continuously ignore the drift phenomenon through the process of reading the normal data of the step S214 by raising or increasing the level of the reference data VREF, there is no need to perform the recovery operation.

When it is determined that the number of the data value “1” is greater than the number of the data value “0” in step S218, the control device 200 may determine that the retention phenomenon occurs in the normal block NM. The semiconductor device 100 may generate the reference data VREF having the third level that is lower than the first level under the control of the control device 200 in step S220. That is, the semiconductor device 100 may decrease the level of the reference data VREF in step S220. Subsequently, the semiconductor device 100 may read at least one of the normal data N_DATA from the normal block NM based on the reference data VREF having the third level and output the output data OUT_DATA corresponding to the read normal data to the control device 200 in step S222. The semiconductor device 100 may read the normal data by reducing or decreasing a level of the reference data VREF, thereby ignoring characteristics in which the data values of the normal data N_DATA change due to the retention phenomenon. Subsequently, the semiconductor device 100 may perform the scrubbing operation on the normal block NM under the control of the control device 200 in step S224. However, if it is possible to continuously ignore the retention phenomenon through the process of reading the normal data of the step S222 by reducing or decreasing the level of the reference data VREF, there is no need to perform the scrubbing operation.

In accordance with the embodiments of the present invention, there are beneficial aspects in that a drift phenomenon or a retention phenomenon may be easily analyzed based on sample data.

In accordance with the embodiments of the present invention, when a drift phenomenon or a retention phenomenon occurring in a storage region or block is easily analyzed and avoided, operational reliability of a semiconductor system may be improved.

For example, although it is described in the embodiments of the present invention that a phenomenon analysis block is included in a control device, the inventive concept is not limited to this and the phenomenon analysis block may be included in a semiconductor device.

While the present invention has been described with respect to specific embodiments, the embodiments are not intended to be restrictive, but rather descriptive. Further, it is noted that the present invention may be achieved in various ways through substitution, change, and modification, by those skilled in the art without departing from the spirit and/or scope of the present invention as defined by the following claims.

What is claimed is:

1. A semiconductor device, comprising:
at least one normal block suitable for storing normal data;
at least one sample block suitable for storing sample data;
a phenomenon analysis block suitable for generating at least one phenomenon analysis signal based on the sample data; and
a control block suitable for controlling a level of reference data required when the normal data are read based on the at least one phenomenon analysis signal.

2. The semiconductor device of claim 1, wherein the sample data have equal proportions of two or more data values that the normal data have.

3. The semiconductor device of claim 1, wherein the control block includes:
a reference data generation unit suitable for generating a plurality of data, each having different levels;
a reference data selection unit suitable for selecting one of the plurality of data as the reference data based on a selection control signal; and
a selection control unit suitable for generating the selection control signal based on the at least one phenomenon analysis signal.

4. The semiconductor device of claim 1, wherein the phenomenon analysis block includes:
a comparison data storage unit suitable for storing comparison data having the same data pattern as a predetermined data pattern of the sample data which have equal proportion of two or more data values that the normal data have;
a data comparison unit suitable for comparing the comparison data with the sample data; and
a rate calculation unit suitable for generating the at least one phenomenon analysis signal, wherein the at least one phenomenon analysis signal includes first and second phenomenon analysis signals corresponding to rates of the data values based on a comparison result of the data comparison unit.

5. The semiconductor device of claim 1, further comprising:
a read circuit block sui table for reading at least one of the normal data or reading the sample data based on the reference data.

6. The semiconductor device of claim 1, wherein the sample block includes a start-gap block.

7. The semiconductor device of claim 1, wherein the sample block is disposed adjacent to the normal block or in the normal block.

8. A semiconductor system, comprising:
a semiconductor device suitable for storing normal data and sample data, wherein the sample data represent characteristics of the normal data; and
a control device suitable for analyzing phenomena occurring in the normal data based on the sample data, wherein the phenomena include a drift phenomenon and a retention phenomenon.

9. The semiconductor system of claim 8, wherein the sample data have equal proportions of two or more data values that the normal data have.

10. The semiconductor system of claim 8, wherein the semiconductor device controls a level of a reference data required when at least one of the normal data is read based on at least one phenomenon analysis signal, which correspond to a result of analyzing the phenomena, generated from the control device.

11. The semiconductor system of claim 10, wherein the semiconductor device includes:
at least one normal block suitable for storing the normal data;
at least one sample block suitable for storing the sample data; and
a control block suitable for controlling the level of the reference data based on the at least one phenomenon analysis signal.

12. The semiconductor system claim 11, wherein the control block includes:
a reference data generation unit suitable for generating a plurality of data, each having different levels;
a reference data selection unit suitable for selecting one of the plurality of data as the reference data based on a selection control signal; and
a selection control unit suitable for generating the selection control signal based on the at least one phenomenon analysis signal.

13. The semiconductor system of claim 11, wherein the semiconductor device further includes:
a read circuit block suitable for reading at least one of the normal data or reading the sample data based on the reference data.

14. The semiconductor device of claim 11, wherein the sample block includes a start-gap block.

15. The semiconductor system of claim 11, wherein the sample block is disposed adjacent to the normal block or in the normal block.

16. The semiconductor system of claim 8, wherein the control device controls a recovery operation or a scrubbing operation of the semiconductor device based on the result of analyzing the phenomena.

17. The semiconductor system of claim 16, wherein the control device includes:
a phenomenon analysis block suitable for generating first and second phenomenon analysis signals corresponding to the phenomena based on the sample data;
a recovery control block suitable for controlling the recovery operation based on the first phenomenon analysis signal; and
a scrubbing control block suitable for controlling the scrubbing operation based on the second phenomenon analysis signal.

18. The semiconductor system of claim 17, wherein the phenomenon analysis block includes:
a comparison data storage unit suitable for storing comparison data having the same data pattern as a predetermined data pattern of the sample data which have an equal proportion of two or more data values that the normal data have;
a data comparison unit suitable for comparing the comparison data with the sample data; and
a rate calculation unit suitable for generating the first and second phenomenon analysis signals corresponding to rates of the data values based on a comparison result of the data comparison unit.

19. The semiconductor system of claim 8, wherein the control device writes the normal data in the semiconductor device through a wear leveling operation.

20. method for driving a semiconductor system, comprising:
analyzing whether a drift phenomenon occurs or a retention phenomenon occurs in at least one normal data based on sample data;
controlling a reference data based on a result of the analysis; and
reading the at least one normal data based on the reference data.

21. The method of claim 20, wherein the analyzing comprises analyzing whether the drift phenomenon occurs or the retention phenomenon occurs in the at least one normal data based on rates of data values of the sample data.

22. The method of claim 20, wherein the controlling of the reference data comprises:
when the drift phenomenon occurs as the result of the analysis, increasing a voltage level of the reference data; and
when the retention phenomenon occurs as the result of the analysis, decreasing the voltage level of the reference data.

23. The method of claim 20, further comprising:
when the drift phenomenon occurs as the result of the analysis, performing a recovery operation on a normal data block where the normal data are stored; and
when the retention phenomenon occurs as the result of the analysis, performing a scrubbing operation on the normal data block.

24. The method of claim 20, wherein the analyzing of the phenomena and the controlling of the reference data are carried out for each normal read operation, for each predetermined period or in consideration of an elapsed time after the normal data are written.
